(19) United States
(12) Patent Application Publication
(10) Pub. No.: US 2022/0250919 A1
(43) Pub. Date: Aug. 11, 2022

(54) SILICON MATERIAL AND METHOD OF MANUFACTURE

(71) Applicant: ionobell, Inc., San Jose, CA (US)

(72) Inventors: Robert C. Ionescu, San Jose, CA (US); Chueh Liu, San Jose, CA (US); Matthew Garrity, San Jose, CA (US)

(21) Appl. No.: 17/667,366

(22) Filed: Feb. 8, 2022

Related U.S. Application Data
(60) Provisional application No. 63/147,484, filed on Feb. 9, 2021.
(60) Provisional application No. 63/273,018, filed on Oct. 28, 2021.

(51) Int. Cl. C01B 33/025; B05D 1/00; B05D 3/02

(52) U.S. Cl. CPC C01B 33/025; B05D 2203/30; B05D 3/02; B05D 1/60

(57) ABSTRACT

A method for coating a silicon material can include mixing the silicon material with a coating reagent, and heating the mixture of the silicon material and the coating reagent to a treatment temperature for a treatment time. The silicon material can optionally include primary particles that are clustered into secondary particles. The resulting coating can optionally include carbon coating, graphite coating, or a polymeric coating.

### CROSS-REFERENCE TO RELATED APPLICATIONS

This application claims the benefit of U.S. Provisional Application No. 63/147,484 filed 9 Feb. 2021 and U.S. Provisional Application No. 63/273,018 filed 28 Oct. 2021, each of which is incorporated in its entirety by this reference.

### TECHNICAL FIELD

This invention relates generally to the silicon mixture field, and more specifically to a new and useful system and method in the silicon mixture field.

### BRIEF DESCRIPTION OF THE FIGURES

FIG. 1 is a schematic representation of the system.

FIGS. 2A, 2B, and 2C are exemplary representations of coated silicon materials.

FIG. 3 is a schematic representation of an exemplary coated silicon material.

FIG. 4 is a flow chart representation of an example of manufacturing a silicon material.

FIG. 5 is a schematic representation of an example of agitating silicon material during a coating process.

FIG. 6 is a schematic representation of an example of reducing a silica precursor to a silicon material.

FIG. 7 is a schematic representation of an example of a silicon material with a plurality of coatings.

FIG. 8 is a schematic representation of an example of a method for preparing a carbon-coated silicon material.

FIG. 9 is a schematic representation of an example of a method for preparing a polymer-coated silicon material.

FIG. 10 is a schematic representation of an example of a method for preparing a carbon-coated silicon material.

FIG. 11 is a schematic representation of an example of a method for preparing a silicon material with a plurality of coatings.

FIGS. 12A-12E are schematic representations of examples of silicon particles.

### DESCRIPTION OF THE PREFERRED EMBODIMENTS

The following description of the preferred embodiments of the invention is not intended to limit the invention to these preferred embodiments, but rather to enable any person skilled in the art to make and use this invention.

### 1. Overview.

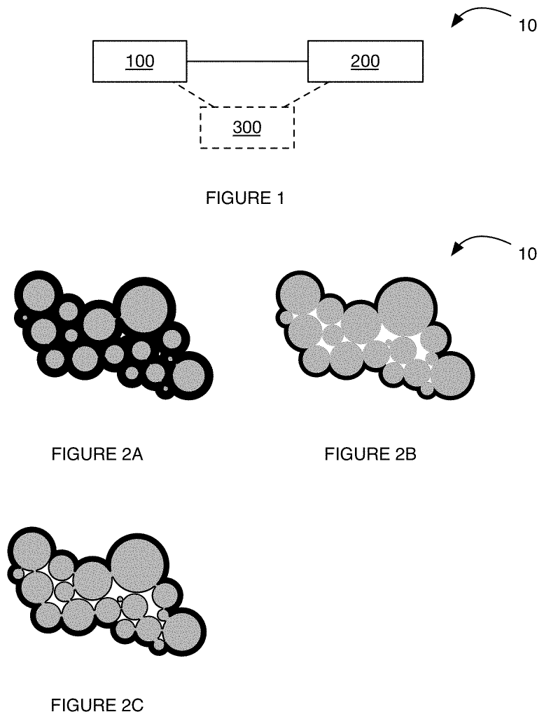

As shown in FIG. 1, the silicon material 10 can include silicon particles 100, one or more coating 200, and optionally one or more additive 300. Exemplary additives include binders 350, conductive materials, stabilizers, cross-linking agents, catalysts, and/or any suitable materials.

As shown for example in FIG. 4, a method 20 for manufacturing and/or processing a silicon material can include: optionally reducing a silica precursor S100, coating a silicon material S200, optionally activating the coating S300, and/or any suitable steps and/or processes.

The silicon material is preferably used to form films of silicon. The silicon films can have any thickness between about 100 nm and 500 μm, but can be thinner than 100 nm or thicker than 500 μm.

The silicon material is preferably used as (e.g., included in) an anode material in a battery (e.g., a Li-ion battery). However, the silicon material can additionally or alternatively be used for photovoltaic applications (e.g., as a light absorber, as a charge separator, as a free carrier extractor, etc.), as a thermal insulator (e.g., a thermal insulator that is operable under extreme conditions such as high temperatures, high pressures, ionizing environments, low temperatures, low pressures, etc.), for high sensitivity sensors (e.g., high gain, low noise, etc.), as a radar absorbing material, as insulation (e.g., in buildings, windows, thermal loss and solar systems, etc.), for biomedical applications, for pharmaceutical applications (e.g., drug delivery), as an aerogel or aerogel substitute (e.g., silicon aerogels), and/or for any suitable application.

### 2. Benefits.

Variations of the technology can confer several benefits and/or advantages.

First, variants of the technology can control and/or modify one or more silicon material properties. For example, coating the silicon material can modify an electrical conductivity, surface area, ionic conductivity, mechanical stability, and/or any suitable property of the silicon material. In an illustrative example, a coating (e.g., carbon coating) can reduce a surface area (e.g., of an external surface of the silicon material) by a factor of at least about 1.5× (e.g., by a factor of 2, 3, 4, 5, 10, 20, 50, values or ranges therebetween, >50) such as reducing a surface area from about 10-20 m²/g to between about 5-10 m²/g. In a second illustrative example, a coating (e.g., a carbon coating, graphitic coating, etc.) can improve an electrical connection between silicon particles (e.g., by forming electrical contacts between the silicon particles).

Second, variants of the technology can improve a homogeneity of a coating of a silicon material. For example, the coating can have a more uniform thickness, more uniform electrical properties, better connection between silicon particles, and/or can otherwise improve a homogeneity of the coating. In a specific example, a homogeneous coating can be enabled by (continuously) agitating the silicon material during the coating process.

However, variants of the technology can confer any other suitable benefits and/or advantages.

As used herein, “substantially” or other words of approximation (e.g., “about,” “approximately,” etc.) can be within a predetermined error threshold or tolerance of a metric, component, or other reference (e.g., within 0.001%, 0.01%, 0.1%, 1%, 5%, 10%, 20%, 30%, etc. of a reference), or be otherwise interpreted.

### 3. Silicon Material

As shown in FIG. 1, the silicon material can include silicon particles, one or more coating 200, and optionally one or more additive 300. Exemplary additives include binders 350, conductive materials, stabilizers, cross-linking agents, catalysts, and/or any suitable materials.

The silicon of the silicon mixture can include silicon particles (e.g., nanoparticles, mesoparticles, macroparticles, microparticles, etc.), silicon clusters, silicon agglomers, silicon aggregates, and/or any suitable silicon materials. The silicon can be porous, solid, and/or have any suitable morphology. The characteristic size of the silicon is preferably between about 100 nm and 100 μm (e.g., 100 nm, 200 nm, 300 n, 500 nm, 1 μm, 2 μm, 5 μm, 10 μm, 20 μm, 50 μm, etc.), but can be any size. The characteristic size can refer to a particle size, an agglomer size, a cluster size, an aggregate size, and/or any suitable size of the silicon material.

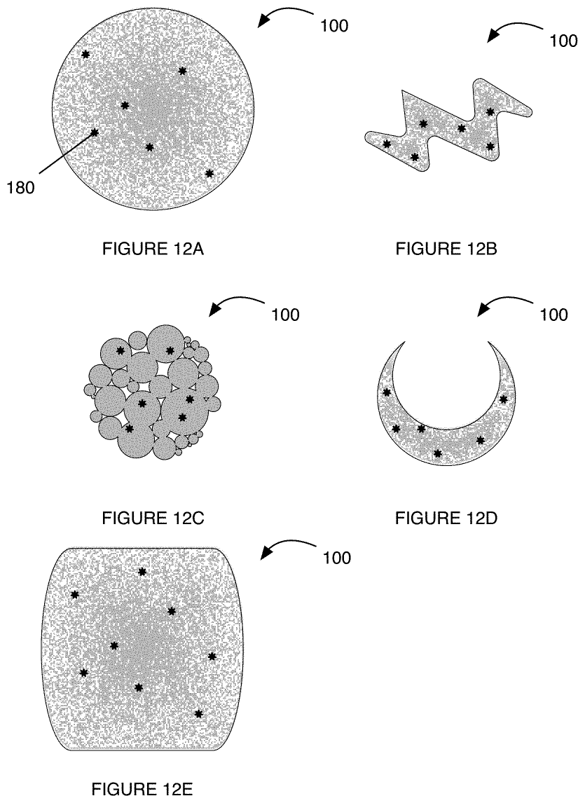

The shape of the particles can be spheroidal (e.g., spherical, ellipsoidal, as shown for example in FIG. 12A or 12C, etc.); rod; platelet; star; pillar; bar; chain; flower; reef; whisker; fiber; box; polyhedron (e.g., cube, rectangular prism, triangular prism, as shown for example in FIG. 12E, etc.); have a worm-like morphology (as shown for example in FIG. 12B, vermiform, etc.); have a foam like morphology; have an egg-shell morphology; have a shard-like morphology (e.g., as shown for example in FIG. 12D); and/or have any suitable morphology.

The particles can be nanoparticles, microparticles, mesoparticles, macroparticles, and/or any suitable particles. The particles can be discrete and/or connected. In variations, the particles can form clusters, aggregates, agglomers, and/or any suitable structures (e.g., higher order structures). A characteristic size of the particles is preferably between about 1 nm to about 10000 nm such as 2 nm, 5 nm, 10 nm, 20 nm, 25 nm, 30 nm, 50 nm, 75 nm, 100 nm, 125 nm, 150 nm, 175 nm, 200 nm, 250 nm, 300 nm, 400 nm, 500 nm, 1000 nm, 1500 nm, 2000 nm, 5000 nm, values or ranges therebetween, and/or other sizes. However, the characteristic size can additionally or alternatively be less than about 1 nm and/or greater than about 10000 nm. In specific examples, the characteristic size can include the radius, diameter, circumference, longest dimension, shortest dimension, length, width, height, pore size, a shell thickness, and/or any size or dimension of the particle. The characteristic size of the particles is preferably distributed on a size distribution. The size distribution can be a substantially uniform distribution (e.g., a box distribution, a mollified uniform distribution, etc. such that the number of particles or the number density of particles with a given characteristic size is approximately constant), a Weibull distribution, a normal distribution, a log-normal distribution, a Lorentzian distribution, a Voigt distribution, a log-hyperbolic distribution, a triangular distribution, a log-Laplace distribution, and/or any suitable distribution.

The particles can be freestanding, clustered, aggregated, agglomerated, interconnected, and/or have any suitable relation or connection(s). For example, the particles (e.g., primary structures) can cooperatively form secondary structures (e.g., clusters) which can cooperatively form tertiary structures (e.g., agglomers). A characteristic size (e.g., radius, diameter, smallest dimension, largest dimension, circumference, longitudinal extent, lateral extent, height, etc.) of the primary structures can be between about 2-150 nm. A characteristic size of the secondary structures can be 100 nm-10 μm. A characteristic size of the tertiary structures can be between about 1 μm and 100 μm. In an illustrative example, secondary particles 140 (e.g., with a size between about 1-10 micrometers) can include primary particles 120 (e.g., with a size between about 10 nm and 1 μm, 10 nm to 100 nm, etc.) that are fused together (e.g., as a result of milling the primary particles). In a variation of this illustrative example, the secondary particles can agglomerate to form agglomers (e.g., tertiary particles 16o). However, the primary, secondary, and/or tertiary structures can have any suitable extent.

The particles can be solid, hollow, porous, and/or have any structure. In some embodiments, particles can cooperatively form pores (e.g., an open internal volume, void space, etc.) within a cluster (and/or a secondary particle can be formed from primary particles). For example, the pores can result from void space that remains after particle packing, because of imperfect packing efficiency (e.g., packing efficiency that is less than an optimal packing efficiency), because of a characteristic size distribution of the particles (e.g., distribution shape, distribution size, etc.), and/or can otherwise result. In a related example, a silicon material can include porous particles and the porous particles can cooperatively form pores. The pore distribution within the particles can be substantially the same as and/or different from (e.g., different sizes, different size distribution, different shape, etc.) the pores cooperatively defined between particles. The pore distribution (e.g., within a porous particle, cooperatively defined between pores, etc.) can have pore size (e.g., average size, mean size, etc.) between about 0.1 nm and about 5 μm, such as 0.2 nm, 0.5 nm, 1 nm, 2 nm, 5 nm, 10 nm, 20 nm, 25 nm, 30 nm, 40 nm, 50 nm, 75 nm, 100 nm, 150 nm, 200 nm, 300 nm, 400 nm, 500 nm, 750 nm, 1 μm, 1.5 μm, 2 μm, 3 μm, 4 μm, and/or 5 μm. However, the pore size can be less than 0.1 nm and/or greater than 5 μm. The pore size distribution can be monomodal or unimodal, bimodal, polymodal, and/or have any suitable number of modes. In specific examples, the pore size distribution can be represented by (e.g., approximated as) a gaussian distribution, a Lorentzian distribution, a Voigt distribution, a uniform distribution (e.g., all pores are within ±1%, ±2%, ±5%, ±10%, ±20%, ±30%, etc. of a common pore size), a mollified uniform distribution, a triangle distribution, a Weibull distribution, power law distribution, log-normal distribution, log-hyperbolic distribution, skew log-Laplace distribution, asymmetric distribution, skewed distribution, and/or any suitable distribution. However, the pores can be described by any suitable distribution.

The pores can have a cubic morphology, hexagonal morphology, random morphology, and/or any suitable morphology. The pore distribution throughout the silicon material can be: substantially uniform, random, engineered (e.g., form a gradient along one or more axes), or otherwise configured.

A porosity of the silicon material is preferably between about 5% and 90%, but can be less than 5% or greater than 90%. The porosity can depend on the silicon morphology (e.g., particle size, characteristic size, shape, etc.), silicon source, impurities in the silicon, the silicon manufacture, and/or any suitable properties. A pore volume of the silicon material is preferably between about 0.02 and 5 cm³g⁻¹, but can be less than 0.02 cm³g⁻¹ or greater than 5 cm³g⁻¹. The pore size of the silicon material is preferably between about 0.5 and 200 nm, but the pore size can be smaller than 0.5 nm or greater than 200 nm.

The external expansion (e.g., external volumetric expansion such as expanding into an environment proximal the silicon material) of the silicon material is preferably at most about 40% (e.g., at most 0.1%, 0.5%, 1%, 2%, 5%, 10%, 15%, 20%, 25%, 30%, −40%, −30%, −25%, −20%, −15%, −10%, −5%, −2%, −1%, −0.5%, −0.1%, etc., or within a range defined therein), with any other expansion being internal expansion (e.g., internal volumetric expansion, inward volume expansion, expansion to fill void space within the material such as to fill pores). However, the external expansion can be the only expansion that occurs and/or the external expansion can be any suitable amount. Examples of expansion sources include: thermal expansion, swelling (e.g., expansion due to absorption of solvent or electrolyte), atomic or ionic displacement, atomic or ionic intercalation (e.g., metalation, lithiation, sodiation, potassiation, etc.), electrostatic effects (e.g., electrostatic repulsion, electrostatic attraction, etc.), and/or any suitable expansion source. The expansion is preferably less than a threshold expansion, because when the expansion (e.g., external expansion) exceeds the threshold expansion, the silicon material, a coating thereof, an SEI layer, and/or other system or application component can break or crack. However, the expansion can be greater than or equal to the threshold expansion.

The exterior surface of the silicon material is preferably substantially sealed (e.g., hinders or prevents an external environment from penetrating the exterior surface). However, the exterior surface can be partially sealed (e.g., allows an external environment to penetrate the surface at a predetermined rate, allows one or more species from the external environment to penetrate the surface, etc.) and/or be open (e.g., porous, include through holes, etc.). The exterior surface can be defined by a thickness or depth of the silicon material. The thickness is preferably between about 1 nm and 10 μm (such as 1 nm, 2 nm, 3 nm, 5 nm, 10 nm, 20 nm, 50 nm, 100 nm, 200 nm, 500 nm, 1 μm, 2 μm, 5 μm, 10 μm, values therebetween), but can be less than 1 nm or greater than 10 μm. The thickness can be homogeneous (e.g., approximately the same around the exterior surface) or inhomogeneous (e.g., differ around the exterior surface). In specific examples, the exterior surface can be welded, fused, melted (and resolidified), and/or have any morphology.

The surface area of the exterior surface of the silicon material (e.g., an exterior surface of the particles, an exterior surface of a cluster of particles, an exterior surface of an agglomer of particles and/or clusters, etc.) is preferably small (e.g., less than about 0.01, 0.5 m²/g, 1 m²/g, 2 m²/g, 3 m²/g, 5 m²/g, 10 m²/g, 15 m²/g, 20 m²/g, 25 m²/g, 30 m²/g, 50 m²/g, values or between a range thereof), but can be large (e.g., greater than 10 m²/g, 15 m²/g, 20 m²/g, 25 m²/g, 30 m²/g, 50 m²/g, 75 m²/g, 100 m²/g, 110 m²/g, 125 m²/g, 150 m²/g, 175 m²/g, 200 m²/g, 300 m²/g, 400 m²/g, 500 m²/g, 750 m²/g, 1000 m²/g, 1250 m²/g, 1400 m²/g, ranges or values therebetween, >1400 m²/g) and/or any suitable value.

The surface area of the interior of the silicon material (e.g., a surface exposed to an internal environment that is separated from with an external environment by the exterior surface, a surface exposed to an internal environment that is in fluid communication with an external environment across the exterior surface, interior surface, etc. such as within a particle, cooperatively defined between particles, between clusters of particles, between agglomers, etc.) is preferably large (e.g., greater than 10 m²/g, 15 m²/g, 20 m²/g, 25 m²/g, 30 m²/g, 50 m²/g, 75 m²/g, 100 m²/g, 110 m²/g, 125 m²/g, 150 m²/g, 175 m²/g, 200 m²/g, 300 m²/g, 400 m²/g, 500 m²/g, 750 m²/g, 1000 m²/g, 1250 m²/g, 1400 m²/g, ranges or values therebetween, >1400 m²/g), but can be small (e.g., less than about 0.01, 0.5 m²/g, 1 m²/g, 2 m²/g, 3 m²/g, 5 m²/g, 10 m²/g, 15 m²/g, 20 m²/g, 25 m²/g, 30 m²/g, 50 m²/g, values or between a range thereof). However, the surface area of the interior can be above or below the values above, and/or be any suitable value.

In some variants, the surface area can refer to a Brunner-Emmett-Teller (BET) surface area. However, any definition, theory, and/or measurement of surface area can be used.

The silicon material can include one or more dopant atoms (e.g., dopants 180). The dopants can be interstitial dopants (e.g., occupy interstitial sites), substitutional dopants (e.g., replace an atom within a lattice or other structure), surface dopants (e.g., occupy surface locations), grains, particles (e.g., with a particle size smaller than a particle of the silicon material, fitting within void space between particles, with a characteristic size between about 1 nm to 1 μm, etc.), form an alloy and/or composite with the silicon, and/or any suitable dopants. The dopants can additionally or alternatively form regions (e.g., grains, islands, etc.) with particles where the regions can be phase segregated, can form bonds (e.g., chemical bonds such as to form an alloy) with the silicon material, occupy void space within the particle, and/or can otherwise be present in the silicon material.

The silicon material preferably includes at most about 45% of dopant (e.g., (e.g., 45%, 40%, 30%, 25%, 20%, 15%, 10%, 5%, 2%, 1%, 0.5%, 0.1%, 2-10%, values or ranges therebetween, etc.). However, the silicon material can additionally or alternatively include greater than 45% dopant. The dopant concentration can refer to a total dopant concentration (e.g., for all dopants when more than one dopant is included), a dopant concentration for a particular dopant, and/or any suitable concentration. The dopant concentration can depend on a target conductivity (e.g., a target electrical conductivity, a target ionic conductivity, etc.), a characteristic particle size, a stabilizing agent concentration, a target mechanical property of the silicon material (e.g., a target mechanical compliance, a target resilience to mechanical stress and/or strain during expansion and/or contraction, etc.), a target capacity (which can be estimated by a linear interpolation between the capacity of silicon and the capacity of the dopant), a function of the dopant, and/or any suitable property. The concentration can be a mass concentration, purity, atomic, stoichiometric, volumetric, and/or any suitable concentration.

The dopant(s) are preferably crystallogens (also referred to as a Group 14 elements, adamantogens, Group IV elements, etc. such as carbon, germanium, tin, lead, etc.). However, the dopant(s) can additionally or alternatively include: chalcogens (e.g., oxygen, sulfur, selenium, tellurium, etc.), pnictogens (e.g., nitrogen, phosphorous, arsenic, antimony, bismuth, etc.), Group 13 elements (also referred to as Group III elements such as boron, aluminium, gallium, indium, thallium, etc.), halogens (e.g., fluorine, chlorine, bromine, iodine, etc.), alkali metals (e.g., lithium, sodium, potassium, rubidium, caesium, etc.), alkaline earth metals, transition metals, lanthanides, actinides, and/or any suitable materials.

In a first specific example, a silicon material can include at least 50% silicon, and between 1-45% carbon, where the percentages can refer to a mass, volumetric, stoichiometric, and/or other suitable percentage of each component. In this specific example, the silicon material can include at most about 5% oxygen.

In a second specific example, a silicon material can include approximately 85-93% silicon, approximately 2-10% carbon, and approximately 5-10% oxygen, where the percentages can refer to a mass percentage of each component. In a first variation of the second specific example, the silicon material can include about 85% silicon, about 5% oxygen, and about 10% carbon. In a second variation of the second specific example, the silicon material can include 85% silicon, 10% oxygen, and 5% carbon. In a third variation of the second specific example, the silicon material can include 93% silicon, 2% carbon, and 5% oxygen. However, the silicon material can have any suitable composition.

In an illustrative example, the silicon material can have a structure that is substantially the same as that described for a silicon material disclosed in U.S. patent application Ser. No. 17/097,814 titled ‘POROUS SILICON MANUFACTURED FROM FUMED SILICA’ filed 13 Nov. 2020, U.S. patent application Ser. No. 17/525,769 titled ‘SILICON MATERIAL AND METHOD OF MANUFACTURE’ filed 12 Nov. 2021, and/or U.S. Provisional Application 63/192,688 titled ‘SILICON MATERIAL AND METHOD OF MANUFACTURE’ filed 25 May 2021, each of which is incorporated in its entirety by this reference. However, the silicon material can have any suitable structure.

In a second illustrative example, the silicon material can be or include porous carbon infused silicon, porous carbon decorated silicon structure, porous silicon carbon hybrid, a porous silicon carbon alloy, a porous silicon carbon composite, silicon carbon alloy, silicon carbon composite, carbon decorated silicon structure, carbon infused silicon, carborundum, silicon carbide, and/or any suitable allotrope or mixture of silicon, carbon, and/or oxygen. For instance, the elemental composition of the silicon material can include SiOC, SiC, SiₓOₓC, SiₓOₓC_{y}, SiOₓC_{y}, SiₓC_{y}, SiOₓ, SiₓO_{y}, SiO₂C, SiO₂Cₓ, SiOCZ, SiCZ, SiₓO_{y}CZ, SiₓOₓCₓZₓ, SiₓCₓZ_{y}, SiOₓZₓ, SiₓOₓZ_{y}, SiO₂CZ, SiO₂CₓZ_{y}, and/or have any suitable composition (e.g., include additional element(s)), where Z can refer to any suitable element of the periodic table and x and/or y can be the same or different and can each be between about 0.001 and 2 (e.g., 0.001, 0.005, 0.01, 0.05, 0.1, 0.5, 1, 2, 0.001-0.05, 0.01-0.5, 0.01-0.1, 0.001-0.01, 0.005-0.1, 0.5-1, 1-2, values or ranges therebetween etc.), less than 0.001, or greater than 2.

In variants of the silicon material that are coated, the coating can function to modify (e.g., enhance, increase, decrease, etc.) an electrical conductivity of the silicon material, improve the stability of the silicon material (e.g., stability of the silicon, stability of an interfacial layer that forms proximal the surface of the silicon such as a solid electrolyte interphase (SEI) layer, etc.), and/or can otherwise function.

The coating 200 (e.g., coating material, coating thickness, etc.) can be selected based on one or more of: the ability of the coating to form a stable interface between an interfacial layer (e.g., an SEI layer, an active material, a battery surface, etc.) and the silicon, ability to inhibit formation of an interfacial layer, coating stability (e.g., stability in an oxidizing environment, stability in a reducing environment, stability in a reactive environment, stability to reaction with specific reactive agents, etc.), electrical conductivity (e.g., electrical conductivity of the coating, target electrical conductivity of the coated silicon, electrical insulative properties, etc.), ion diffusion rate (e.g., Li⁺ diffusion rate through the coating; ion conductivity), coating elasticity, silicon porosity, silicon expansion coefficient (e.g., external expansion coefficient, external volumetric expansion, etc.), SEI layer formation (e.g., promotion and/or retardation), and/or otherwise be selected.

The coating can attach to an outer surface of the silicon, infiltrate the pores, coat a portion of the silicon (e.g., portion of the silicon possessing a predetermined quality), and/or otherwise coat the silicon. The coated silicon preferably lacks an additional SEI layer over the coating, but can alternatively have an SEI layer thereon.

The coating material preferably includes carbonaceous material (e.g., organic molecules, polymers, inorganic carbon, nanocarbon, amorphous carbon, etc.), but can additionally or alternatively include inorganic materials, plasticizers, biopolymeric membranes, ionic dopants, and/or any suitable materials. Examples of polymeric coatings include: polyacrylonitrile (PAN), polypyrrole (PPy), unsaturated rubber (e.g., polybutadiene, chloroprene rubber, butyl rubber such as a copolymer of isobutene and isoprene (IIR), styrene-butadiene rubber such as a copolymer of styrene and butadiene (SBR), nitrile rubber such as a copolymer of butadiene and acrylonitrile, (NBR), etc.), saturated rubber (e.g., ethylene propylene rubber (EPM), a copolymer of ethene and propene; ethylene propylene diene rubber (EPDM); epichlorohydrin rubber (ECO); polyacrylic rubber such as alkyl acrylate copolymer (ACM), acrylonitrile butadiene rubber (ABR), etc.; silicone rubber such as silicone (SI), polymethyl silicone (Q), vinyl methyl silicone (VMQ), etc.; fluorosilicone rubber (FVMQ); etc.), and/or any suitable polymer(s). Examples of carbonaceous coatings include: carbon super P, acetylene black, carbon black (e.g., C45, C65, etc.), mesocarbon microbeads (MCMB), graphene, carbon nanotubes (CNTs) (e.g., single walled carbon nanotubes, multiwalled carbon nanotubes, semi-conducting carbon nanotubes, metallic carbon nanotubes, etc.), reduced graphene oxide, graphite, fullerenes, and/or any suitable coating materials. The coating can include a mixture of coating materials, where the ratio and/or relative amounts of the constituents can be selected based on any suitable coating property.

In variants of the coating that include carbon (e.g., an allotrope of carbon such as graphite, graphene, carbon nanotubes, diamond, fullerenes, etc.), the composition of the coating is preferably at least 90% carbon. For instance, when a coating comprises graphite, preferably at least about 90% (for the given coating layer, total amount of all coatings, etc.) of the coating material is graphite (e.g., at most about 10% of the coating material is non-graphitic carbon), which can be beneficial as nongraphite carbon generally will not significantly contribute to capacity when the silicon material is incorporated in a battery or other application. However, in these (or other) variants, the composition of the coating can include less than 90% carbon (e.g., 80%, 70%, 60%, 50%, etc.), for instance, to balance a coating property such as mechanical resilience, stability, conductivity (e.g., electrical, ionic, etc.), target capacity, and/or other coating property.

The coating can be electrically insulating, semiconducting, electrically conductive, and/or have any suitable electrical properties. The coating is preferably ionically conductive (e.g., enables the diffusion or transport of ions through), but can be ionically insulating. In some variants, when the coating swells (e.g., in response to expansion of the silicon material), the ionic conductivity of the coating can be increased.

The coating thickness is a value or range thereof preferably between about 1 nm and 20 μm such as 1 nm, 2 nm, 3 nm, 5 nm, 10 nm, 20 nm, 30 nm, 5o nm, 100 nm, 200 nm, 50o nm, 1 μm, 2 μm, 5 μm, 10 μm, or values or ranges therebetween. However, the coating thickness can be less than 1 nm or greater than 20 μm. The coating thickness can be substantially uniform (e.g., thickness vary by at most 1%, 2%, 5%, 10%, 20%, etc.; homogeneous; etc.) or nonuniform (e.g., inhomogeneous) over the extent of the silicon material. For instance, the coating thickness can form a thickness gradient such as being thicker closer to the external exposed surface of the silicon material. In another example, the coating can have a first thickness on internal surfaces of the silicon material and a second thickness (generally, but not always, greater than the first thickness) on external surfaces of the silicon material. In another example, the coating thickness can be between about 1 nm and about 1 μm (e.g., 1-10 nm, 1-100 nm, 10-100 nm, 20-50 nm, 25-100 nm, 1-25 nm, 1-20 nm, 2-10 nm, 5-10 nm, 50-100 nm, 50-500 nm, 0.9-1100 nm, 0.8-1200 nm, etc.; over an external surface of the silicon; over an internal surface of the silicon; over an exposed surface such as internal and/or external surface of the silicon; etc.). The coating thickness is preferably chosen to allow ions (e.g., Li⁺ ions) and/or other materials (e.g., electrolytes) to penetrate the coating. However, the coating can be impenetrable to ions, can include one or more pores and/or perforations to enable the materials (e.g., ions) to pass through (e.g., at predetermined locations), and/or otherwise be permeable to one or more substances. The coating thickness can depend on the coating material, the material of one or more other coatings, the silicon material, and/or otherwise depend on the silicon material.

In a first illustrative example as shown in FIG. 2C, the coating thickness can be a first thickness on an exterior surface of the silicon material and a second thickness on an interior surface of the pores. In a second illustrative example as shown in FIG. 2B, the coating can coat the external surface of the silicon material without entering the pores. In a third illustrative example, as shown in FIG. 2A, the coating can substantially uniformly coat the exposed surface area of the silicon material (e.g., the area inside the pores and the external surface of the silicon material).

The coating is preferably ductile (e.g., has a high yield point, resists fracturing, has a large modulus of toughness, flexible, elastic, etc.), but can be brittle (e.g., has a low yield point, has a small modulus of toughness, undergoes fracturing, etc.) and/or can have any suitable elastic and/or plastic behavior. Use of a ductile coating can function to facilitate accommodation of volume expansion (e.g., external volume expansion) of the silicon material without cracking or otherwise distorting the coating. In an illustrative example, the coating can be a mechanically resilient coating, where the coating can expand and contract to accommodate for stresses experienced during expansion and/or contraction of the underlying silicon material (e.g., during lithiation). The stresses preferably do not crack (e.g., do not form cracks; cracks that form do not permit external environment from reaching the underlying silicon material; cracks have a size less than a threshold size such as 1 nm thick, 2 nm thick, 5 nm thick, 10 nm thick, etc.; cracks form at most a threshold length such as 100 nm, 50o nm, 1 μm, 2 μm, 5 μm, 10 μm, etc.; cracks do not form for a threshold number of expansion/contraction cycles such as 10 cycles, 100 cycles, 200 cycles, 250 cycles, 500 cycles, 1000 cycles, 2000 cycles, 5000 cycles, etc.; etc.) the mechanically resilient coating (e.g., do not expose the underlying silicon material); however, cracks or other changes in the coating may occur.

However, in some variants, brittle (or less elastic) coatings can be used, particularly when elastic SEI layers can be formed. These elastic SEI layers (e.g., formed by a reaction between the electrolyte and the silicon; otherwise formed; etc.) can additionally or alternatively be used with elastic coatings, when the silicon material is not coated, and/or with any suitable silicon material. In these variants, when the coating cracks (e.g., after expansion of the silicon material due to lithiation), the exposed silicon material can contact the electrolyte and form an organic or polymer-like SEI layer (e.g., including organic or polymer-like compounds such as Li alkyl carbonates). These organic or polymer-like compounds can be elastic to facilitate deformation (e.g., with or without breaking) when the silicon material expands and contracts. However, brittle (or less elastic) coatings can otherwise be used.

In a specific example, an elastic SEI layer can be formed on an uncoated silicon material. In this specific example, when the silicon material expands or contracts, the SEI layer can expand or contract without breaking. In a variation of this specific example, an elastic SEI layer can be formed on a silicon material with an elastic coating, where both the coating and the SEI layer can expand or contract with changes in the silicon material size.

However, any suitable coating can be used.

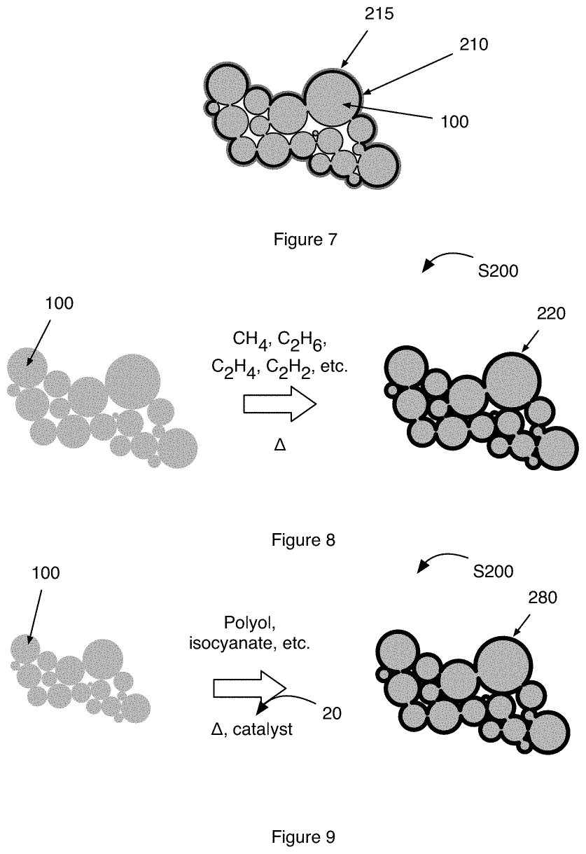

In variants (as shown for example in FIG. 7), the silicon material can include more than one coating (such as a first coating 210 and a second coating 215). The coatings can be the same or different. In a first example (as shown for example in FIG. 11), the silicon material can include a carbon coating 220 (e.g., graphite coating) that is then coated with a polymeric coating 280. In a second example, the silicon material can include a first polymeric coating that is then coated with a second polymeric coating. In a third example, the silicon material can include a polymeric coating that is then coated with a carbonaceous coating. However, any suitable coatings can be used.

In some variants, the silicon material can be mixed with (e.g., blended with) carbon material (where the term silicon material can include silicon material mixed with carbon material). The carbon material can be derived from waste materials (e.g., waste material leftover from other processes), recycled carbon, plastics, virgin materials, and/or otherwise be derived. The ratio of silicon to carbon material can be between about 10:1 and 0.1:1. However, the ratio of silicon material to carbon material can be greater than 10:1 or less than 0.1:1. The carbon material and silicon material are preferably substantially homogeneously mixed, but can be inhomogeneously mixed. In an illustrative example, the carbon material can include a carbon material as disclosed in U.S. patent application Ser. No. 16/222,074 filed 17 Dec. 2018 titled ‘HIGH PERFORMANCE CARBONIZED PLASTICS FOR ENERGY STORAGE’ incorporated in its entirety by this reference. However, any suitable carbon material can be mixed with the silicon material.

The optional additives 300 function to modify one or more property of the mixture and/or of a film derived from the mixture. Examples of mixture properties include: viscosity, boiling point, conductivity (e.g., electrical conductivity, thermal conductivity, etc.), solubility (e.g., of the silicon material, of other additives such as a binder, of coating materials, etc.), stability (e.g., amount of time the materials remain suspended, stability to chemical reactions, etc.), and/or other properties of the slurry. Examples of film properties include: film adhesion to a surface, film reactivity, film conductivity (e.g., electrical conductivity, thermal conductivity, ion conductivity, etc.), film stability (e.g., resistance to chemical reaction), film thickness (e.g., maximum film thickness, minimum film thickness, etc.), performance properties (e.g., cyclability, energy density, capacitance, etc.), and/or any suitable properties. Examples of additives include: binders (e.g., adhesives), conductive materials, stabilizers, crosslinking agents, catalysts, auditors (e.g., hydrophilic auditors, hydrophobic auditors, etc. which can function to measure, monitor, adjust, etc. a hydrophobicity or hydrophilicity of the mixture), antioxidants, electrolytes, metalizing materials, insulating material, semiconducting material, and/or any suitable material(s).

The additives are preferably elastic, but can be rigid, semi-rigid, and/or have any suitable mechanical properties. The additives are preferably ionically conductive (e.g., enable transport of ions such as Li⁺ with at least an ionic conductivity of 0.1 mS/cm), but can facilitate diffusion of ions, be ionically insulating (e.g., inhibit or slow ion conductivity, have an ionic conductivity less than about 0.1 mS/cm), and/or have any suitable ionic conductivity.

The silicon material and additives are preferably substantially homogeneously mixed, but can be inhomogeneously mixed. The additives can coat the silicon material (and/or a coating thereof), coat a portion of the silicon material, can be attached to the silicon material (e.g., via a chemical bond, via physical adhesion, via Van Der Waals forces, etc.), and/or can otherwise be mixed with the silicon material.

The silicon material to additive ratio (e.g., mass ratio, volume ratio, stoichiometric ratio, etc.) can be any value or range between about 1 part silicon to 10 parts additive and 10 parts silicon material to 1 part additive. For example, the silicon mixture can include between about 10% and 80% silicon material and between about 5% and 85% additive. However, the silicon material to additive ratio can be 1 part silicon to greater than 10 parts additive, greater than 10 parts silicon material to 1 part additive, and/or any suitable ratio.

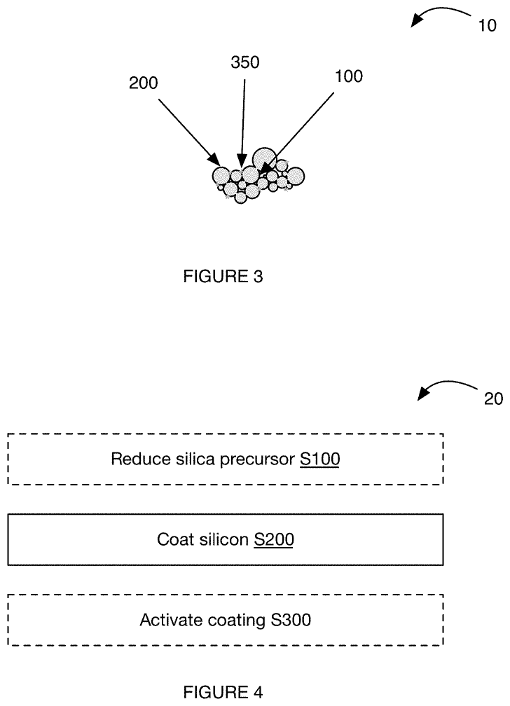

The binder(s) 350 preferably function to couple (e.g., bind, generate a retention force between, etc.) the silicon material to the coating (as shown for example in FIG. 3), but can additionally or alternatively function to couple the silicon material to a surface (e.g., substrate, a battery surface, cathode, anode, etc.), and/or can otherwise function. The binders can include organic and/or inorganic material. Examples of binders include: carboxymethyl cellulose (CMC), styrene-butadiene rubber (SBR), poly(acrylic acid) (PAA), sodium alginate (SA), polyvinylidene fluoride (PVDF), polyaniline (PANI), poly(9,9-dioctylfluorene-cofluorenone-co-methyl benzoic ester) (PFM), polytetrafluoroethylene (PTFE), poly(ethylene oxide) (PEO), polyvinyl alcohol (PVA), polyacrylonitrile (PAN), sodium carboxymethyl chitosan (CCTS), poly(3,4-ethylenedioxythiophene) polystyrene sulfonate (PEDOT:PSS), 3,4-propylenedioxythiophene (ProDOT), dopamine hydrochloride, polyrotaxanes, polythiophene, combinations thereof, and/or any suitable binder.

In some variants, the binder can be the same as (e.g., the same material as) the coating on the silicon material. In these variants, the coating can function as binder, the binder can form a coating on the silicon material, a separate coating and binder can be used, and/or the coating and binder can otherwise be used.

The conductive material preferably functions to ensure that films of the silicon material have a substantially uniform electrical conductivity, but can otherwise function. For example, the conductive material can be added to modify an electrical conductivity of the silicon film to be at least about 10,000 siemens/meter (S*m⁻¹), can modify a resistivity of the silicon film to be at most about 10-4 n m, etc.), and/or can otherwise modify an electrical property of the silicon film and/or silicon mixture.

The conductive material preferably includes carbonaceous material(s) (e.g., organic, inorganic carbon, nanocarbon, polymeric, organo-metallic, etc.), but can additionally or alternatively include inorganic material(s) (e.g., noncarbonaceous material, metals, semi-metals, semiconductors, etc.). Examples of conductive materials include: carbon super P, acetylene black, carbon black (e.g., C45, C65, etc.), mesocarbon microbeads (MCMB), graphene, carbon nanotubes (CNTs) (e.g., single walled carbon nanotubes, multiwalled carbon nanotubes, semi-conducting carbon nanotubes, metallic carbon nanotubes, etc.), reduced graphene oxide, graphite, fullerenes, polymers, combinations thereof, and/or any suitable material(s).

In some variants, the conductive material can be the same as (e.g., the same material as) the coating on the silicon material and/or the binder. In these variants, the coating can function as conductive material, the conductive material can form a coating on the silicon material, a separate coating and conductive material can be used, the binder can function as conductive material, the conductive material can function as a binder, a separate binder and conductive material can be used, and/or the binder, coating, and conductive material can be otherwise related.

In a specific example, a silicon material can include graphite and carbon black (e.g., C65) in a ratio of about 6:1. However, any suitable conductive material(s) can be used and/or in any suitable ratio (e.g., in the above specific example the graphite to carbon black ratio could be any ratio between 10:1 to 1:10).

In some embodiments, one or more material within the system can undergo embrittlement (e.g., crack), exhibit nonideal (e.g., poor, insufficient, etc.) adhesion, and/or can experience other detrimental properties or effects. As an illustrative example, PAN-coated silicon particles (particularly when the PAN is cyclized) can exhibit cracking, embrittlement, and/or poor adhesion to substrates. One or more additives (particularly, but not exclusively, stabilizers, catalysts, and/or crosslinking agents) can be added to the silicon mixture to mitigate (e.g., minimize, prevent, decrease, etc.) the detrimental properties or effects. For example, polyols (e.g., polycarbonatediols such as Duranol™; polyethylene glycol; polytetrahydrofuran; hydroxyl-terminated polybutadiene; polycaprolactone polyols, polysulfide polyols, etc.), isocyanates (e.g., aliphatic diisocyanates such as hexamethylene diisocyanate (HDI); cycloaliphatic diisocyanates such as isophorone diisocyanate (IPDI), 4,4′ diisocyanate methylenedicyclohexane (HMDI), etc.; aromatic diisocyantes such as toluene diisocyanate (TDI), methylene diphenyl diisocyanate (MDI), etc.; etc.), catalysts (e.g., metallic soaps such as dibutyltin dilaurate (DBTDL), dibutyltin dioctanoate, etc.; amines such as triethylenediamine, dimethylcyclohexylamine, dimethylethanolamine, bis-(2-dimethylaminoethyl)ether, etc.; oxides; mercaptides; etc.), and/or any suitable additives can be introduced (for instance to form polyurethane, form polyester, to crosslink the polymer coating, to form binder, etc.). These additives are typically added in a relatively small percentage (e.g., before shrinkage or material loss) such as less than about 5% (e.g., by weight, mass, volume, stoichiometry, etc.), but can be added at any suitable percentage (e.g., greater than 5%). As an illustrative example, a silicon material (e.g., dried material) can include about 70% silicon, about 30% PAN (e.g., before material loss or decrease during cyclization, where upto half of the material can be lost), and about 1-2% polyurethane (and/or starting products therefore) can be included. In a variation of this illustrative example, such as after shrinkage or loss of PAN, the composition of the silicon material (e.g., dry silicon material) can be about 80% silicon, about 17% PAN (e.g., cyclized PAN), and about 3% polyurethane.

In a first illustrative example, a coated silicon material can include about 75% silicon (e.g., 70-80% silicon), about 10% conductive material (e.g., graphite, C65, etc.; such as 5-15%), and about 15% polymer (e.g., PAA, CMC, SBR, PAN, etc.; such as 10-20%), where the percentages can refer to a mass percentage, volume percentage, stoichiometric percentage, purity percentage, and/or to any suitable percentage.

In a second illustrative example, a coated silicon material can include about 70% silicon (e.g., 65-75% silicon) and about 30% polymer (e.g., PAA, CMC, SBR, PAN, etc.; such as 25-35%), where the percentages can refer to a mass percentage, volume percentage, stoichiometric percentage, purity percentage, and/or to any suitable percentage. In a variation of this specific example, the polymer can be cyclized, undergo shrinkage, and/or otherwise be modified. This modification can change the relative composition of the material to closer to about 85% silicon and about 15% polymer (e.g., an approximately 2× modification), and/or can otherwise modify the relative composition of the silicon material.

In a third illustrative example, a coated silicon material can include about 85% silicon (e.g., 80-90% silicon), about 15% graphitic carbon (e.g., 10-20%), and about 2.5% C65 (e.g., 0-5%), where the percentages can refer to a mass percentage, volume percentage, stoichiometric percentage, purity percentage, and/or to any suitable percentage.

In a fourth illustrative example, a coated silicon material can include about 75% silicon (e.g., 70-80% silicon), about 12.5% graphite (e.g., 10-15%), about 5% polymer (e.g., PAA, CMC, SBR, PAN, etc.; such as 2.5-10%), and about 5% conductive material (e.g., C65, carbon black, etc.; such as 2.5-10%); where the percentages can refer to a mass percentage, volume percentage, stoichiometric percentage, purity percentage, and/or to any suitable percentage.

In variations of the above illustrative examples, dopants are preferably included in the silicon percentage (e.g., 75% silicon refers to a percentage of silicon particles taken as a whole). However, the silicon percentage can refer to a silicon purity (e.g., where dopants can be included in a carbon concentration for example), and/or the silicon and/or dopant concentrations can otherwise be considered.

However, the silicon material can include any suitable materials.

### 4. Method

As shown for example in FIG. 4, a method for manufacturing and/or processing a silicon material can include: optionally reducing a silica precursor S100, coating a silicon material S200, optionally activating the coating S300, and/or any suitable steps and/or processes. The method preferably functions to coat a silicon material (e.g., to prepare a silicon material as described above), but can additionally or alternatively function to generate the silicon material, activate the coating, modify a coating property to achieve a target property, modify the silicon material to achieve a target property (e.g., surface area, electrical conductivity, ionic conductivity, etc.), and/or can otherwise function.

The method and/or steps thereof can be performed in a single chamber (e.g., a furnace, an oven, etc.) and/or in a plurality of chambers (e.g., a different chamber for each step or substep, a heating chamber, a coating chamber, a milling chamber, a washing chamber, etc.). The method can be performed on a laboratory scale (e.g., microgram, milligram, gram scale such as between about 1 μg and 999 g, etc.), manufacturing scale (e.g., kilogram, megagram, etc. such as between about 1 kg and 999 Mg), and/or any suitable scale.

In some variants, the method can process a silica precursor to form the silicon material. In these variants, the silica is typically reduced to silicon (e.g., according to S100) before coating. However, the silica can be coated before and/or at the same time as it is reduced. Additionally or alternatively, the method can produce a coated silica material. Examples of silica precursors include: waste silica (e.g., silica generated as a byproduct from another process such as waste, residual, etc. silica from a silicon purification process; silica produced during silicon production for solar, semiconductor, etc.; silica that would otherwise be disposed of; etc.), recycled silica (e.g., silica recycled or repurposed after a different use), pristine silica (e.g., newly manufactured silica), and/or any suitable silica starting material. Exemplary silica starting materials (e.g., silica precursors) include: sol-gel silica (e.g., silica prepared according to the Stöber method), fume silica, diatoms, glass, quartz, fumed silica, silica fumes, Cabosil fumed silica, aerosil fumed silica, sipernat silica, precipitated silica, silica gels, silica aerogels, decomposed silica gels, silica beads, silica sand, and/or any suitable silica material.

Additionally or alternatively, the method can process silicon (e.g., silicon particles, silicon materials as disclosed in U.S. patent application Ser. No. 17/097,814 titled ‘POROUS SILICON MANUFACTURED FROM FUMED SILICA’ filed 13 Nov. 2020, U.S. patent application Ser. No. 17/525,769 titled ‘SILICON MATERIAL AND METHOD OF MANUFACTURE’ filed 12 Nov. 2021, and/or U.S. Provisional Application 63/192,688 titled ‘SILICON MATERIAL AND METHOD OF MANUFACTURE’ filed 25 May 2021, each of which is incorporated in its entirety by this reference) and/or any suitable silicon containing material. In a specific example, the method can be performed using a high-purity silicon material (e.g., a silicon material with at least 90% Si purity such as 95%, 97%, 98%, 99%, 99.5%, 99.9%, 99.99%, 99.995%, 99.999%, values therebetween, etc.; silicon material with at most about 1%, 0.5%, 0.1%, 0.05%, 0.01%, 0.005%, 0.001%, etc. of aluminium, calcium, iron, titanium, oxygen, and/or other impurities or inclusions). In a variation of the first specific example, the silicon material can include sub-100 nm silicon particles. In a second variation of the first specific example, the silicon material can include 100 nm to 100 μm silicon particles (e.g., 0.3 μm nanoparticles, 2-5 μm particles, 1-5 μm particles, 0-5 μm particles, 0-10 μm particles, 0-20 μm particles, etc.; that can be manufactured by milling, co-welding, fusing, annealing, etc. smaller silicon particles such as 10 nm to 1 μm particles). In a third specific example, the silicon material can include silicon particles with a narrow size distribution (such as 3 μm particles with a size distribution that is ±100 nm, ±200 nm, ±500 nm, ±1 μm, etc.; 3.5 μm particles with a size distribution that is ±100 nm, ±200 nm, ±500 nm, ±750 nm, ±1 μm, etc.; 5 μm particles with a size distribution that is ±100 nm, ±500 nm, ±1 μm, ±2 μm, ±3 μm, etc.; 10 μm particles with a size distribution that is ±100 nm, ±500 nm, ±1 μm, ±3 μm, ±5 μm, ±7.5 μm, etc.; particles with a variance or deviation of ±0.1%, ±0.5%, ±1%, ±2%, ±3%, ±4%, ±5%, ±10%, 20%, values or ranges therebetween, <0.1%, etc. relative to a mean or other characteristic size of the particles; etc.). However, the silicon particles can have a large size distribution (e.g., where the distribution can become smaller during operation or use of the material as smaller particles aggregate, cluster, agglomerate, degrade, etc. during use) and/or any suitable size distribution. In this specific example, the silicon particles can be solid, hollow, porous, and/or have any suitable morphology. In this specific example, the silicon material can have a large surface roughness (e.g., features that are ±100 nm, ±200 nm, ±500 nm, ±1 μm, ±2 μm, ±5 μm, ±10 μm, ±50 μm, values or ranges therebetween, etc.), a small surface roughness (e.g., features that are smaller than about 100 nm), and/or any suitable feature sizes. However, any suitable materials can be prepared and/or used in this method.

Reducing a silica precursor S100 preferably functions to reduce the silica precursor to a silicon material. The silica precursor can be fully or partially reduced to silicon. For instance, the resulting silicon material can include an oxygen content between about 0-20% (e.g., where the remainder can include carbon, silicon, etc.). The silica precursor can be reduced in a furnace, oven, sealed chamber, barrel, and/or in any suitable container. The silica can be reduced in an inert atmosphere (e.g., 95% or greater nitrogen, helium, neon, argon, krypton, xenon, CO₂, combinations thereof, etc. by pressure, mass, volume, composition, etc.), in a reducing environment (e.g., hydrogen gas), in an oxidizing environment (e.g., to remove or oxidize impurities, oxidizing to species other than silicon, etc.), and/or in any suitable environment.

As shown for example in FIG. 6, reducing a silica precursor can include: purifying the silica precursor S110, exposing the silica to reaction modifiers S120, purifying the silica and reaction modifier mixture S130, comminuting the silica S140, reducing the silica to silicon S150, purifying the silicon S160, processing the silicon S170, and/or any suitable steps or processes.

As an illustrative example, reducing the silica precursor can include: optionally mixing the silica precursor with a salt (e.g., sodium chloride), mixing (e.g., agitating, milling, comminuting, etc.) the silica precursor with a reducing material (e.g., magnesium, aluminium, etc.), and heating the silica precursor to a reduction temperature (e.g., 500° C., 600° C., 700° C., 800° C., 900° C., 1000°, 1200° C., temperatures therebetween, etc.) for between 1-24 hours. In variants of this illustrative example, the silica precursor can be heated to one or more intermediate temperatures (e.g., a temperature below the reduction temperature; 200° C., 250° C., 300° C., 400° C., 500° C., 600° C., 700° C., values therebetween, etc.; etc.) for an amount of time (e.g., 30 minutes to 24 hours) before heating the silica precursor to the reduction temperature. The silica precursor and/or the resulting silicon can be washed using solvent(s) (e.g., water, alcohol, ether, etc.), acid (e.g., HCl, HF, HBr, HI, HNO₃, H₂SO₄, etc.), base (e.g., alkali metal hydroxides, alkaline earth hydroxides, etc.), surfactants (e.g., soaps), and/or using any suitable materials. The silica precursor and/or the resulting silicon can be milled (e.g., using a ball mill) such as at a milling speed between about 1-2500 RPM (e.g., 500 RPM, 600 RPM, 700 RPM, 800 RPM, 900 RPM, 1000 RPM, 1500 RPM, 2000 RPM, etc.) for between about 30 minutes and 24 hours (e.g., 1 hour, 2 hours, 3 hours, 4 hours, 6 hours, 8 hours, 10 hours, 12 hours, 15 hours, 18 hours, 20 hours, 24 hours, values or ranges therebetween, etc.). In variations of this illustrative example, silicon starting materials can be processed in a similar manner to silica and/or silicon from reduced silica (e.g., washing, milling, etc.). However, the silica precursor can otherwise be reduced.

Coating the silicon material S200 functions to coat the silicon material (e.g., from S100, silicon precursor, silicon starting material, etc.). The silicon material is preferably coated with a material as described above, but additionally or alternatively be coated with any suitable material(s). For example, the silicon can be coated with carbonaceous material(s) (e.g., polymers, graphite, graphene, carbon nanotubes, carbon nanowires, fullerenes, carbon black, etc.), polymeric materials (e.g., polymeric lithium), and/or any suitable material(s). The coating properties (e.g., coating thickness, coating homogeneity, electronic properties, ionic transport, etc.) can depend on and/or be independent of a coating parameter (e.g., coating starting materials, coating time, coating temperature, coating pressure, coating atmosphere, etc.). The silicon material can be coated in the same and/or a different chamber (e.g., vacuum chamber) or vessel (e.g., furnace) as silica is reduced in.

The silicon material can be coated in an open or enclosed environment. Examples of enclosed environments include: ovens, furnaces (e.g., tube furnaces, belt furnaces, etc.), chambers (e.g., deposition chambers, sputtering chambers, etc.), and/or any suitable enclosed environment can be used. The silicon material is preferably coated in a chamber (e.g., enclosed environment) with a volume between about 1 L to 500 L, but can be coated in chambers with volumes less than 1 L or greater than 500 L. The enclosed chamber can include one feed port or a plurality of feed ports, where the feed ports function to inject coating precursors and/or silicon material into the coating environment. The coating environment can be an inert atmosphere, reducing atmosphere, and/or oxidizing atmosphere.

The coating time (e.g., total time for coating; time the silicon material and/or coating agents are maintained at a coating temperature, coating pressure, etc.; etc.) can be any amount of time between about 30 minutes and 24 hours (e.g., 1 hour, 2 hours, 4 hours, 6 hours, 8 hours, 12 hours, 15 hours, 18 hours, 24 hours, etc.), less than 30 minutes, and/or greater than 24 hours.

The coating agents 470 (e.g., coating reagents) can include: methane, ethane, ethene, ethyne, propane, propene, propyne, butane, butene, butyne, carbon, polymers, monomers (e.g., one or more monomers that can form a target polymer), oligomers, and/or any suitable agents.

Coating the silicon material can include: in situ coating formation (e.g., in situ polymerization), polymerization (e.g., sol-gel polymerization, step-growth polymerization, chain-growth polymerization, photopolymerization, plasma polymerization, radical polymerization, etc.), deposition (e.g., chemical vapor deposition, atomic layer deposition, physical vapor deposition, plasma enhanced chemical vapor deposition, etc.), reduction or decomposition (e.g., thermal decomposition of polymer, thermal decomposition of organic material, chemical decomposition, etc.), exposing the silicon material to one or more coating reagents, and/or any suitable coating method(s) can be used.

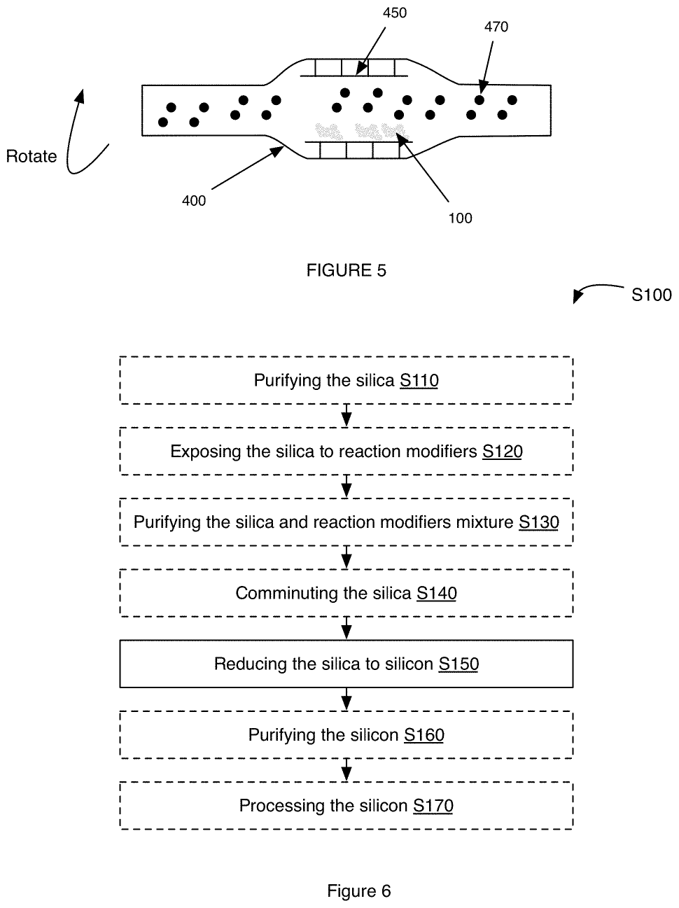

The silicon material is preferably agitated during the coating process, which can function to improve a uniformity (e.g., homogeneity) of the coating. However, the silicon material can be stationary, and/or otherwise in motion. The silicon material can be agitated continuously, intermittently, periodically, at predetermined times, with a predetermined frequency, randomly, responsive to an input, and/or with any suitable timing. The silicon material can be agitated manually or automatically. The silicon material is preferably agitated in a turbulent manner (e.g., such that multiple surfaces of the silicon become exposed during agitation), but can be agitated in a consistent manner (e.g., such that a common surface of the silicon material is exposed in a predetermined manner, pattern, etc.), and/or can otherwise be agitated. The silicon material can be agitated by an agitator, by moving or modulating the coating chamber, and/or can otherwise be agitated. Examples of agitators include blades (e.g., linear blades, helical blades, etc.), magnetic stirrers, cross-stirrers, vortex mixers, drum mixers, shakers, and/or any suitable agitator(s) can be used. In an illustrative example, as shown in FIG. 5, silicon material can be coated in a furnace 400 (e.g., tube furnace), where the furnace includes a set of blades 450 (e.g., 1 blade, 2 blades, 3 blades, 4 blades, 10 blades, 20 blades, a number of blades there between, >20 blades, etc.) that agitate the silicon material when the tube furnace is rotated. The blades can be arranged parallel to a reference axis (e.g., a rotation axis; a longitudinal or lateral axis of the furnace, etc.), perpendicular to the reference axis, and/or intersect that reference axis at any angle(s). However, the silicon material can otherwise be agitated.

In some variations, dopants of the silicon material can lead to (e.g., promote) a more homogeneous coating. In an illustrative example, carbon dopants (particularly dopants near the particle surface) can act as coating growth sites (where the coating growth can then propagate from the growth sites). In another illustrative example, an inhomogeneous dopant distribution can lead to an inhomogeneous coating (e.g., where the coating can be partially matched to the dopant distribution). In another illustrative example, carbon dopants can diffuse to (e.g., proximal to, within a threshold distance of, etc.) a surface of the silicon material, which can promote a conformal (e.g., uniform, homogeneous, etc.) carbon coating (e.g., with graphene, graphite, amorphous carbon, etc.).

In a first illustrative example, a silicon material can be coated by: mixing (e.g., stirring, sonicating, etc.) one or more polymer precursors (e.g., monomers such as phytic acid and pyrrole for PPy) and the silicon material in a solvent (e.g., isopropanol); dissolving an initiating agent (e.g., radical generator, oxidizing agent, reducing agent, etc.; such as ammonium persulfate (APS)) in a solvent (e.g., water); mixing the precursor/silicon material solution and the initiating agent solution for between 1-24 hours (e.g., at or near room temperature such as 0-50° C.); washing (e.g., diluting with water and centrifuging to collect the material) the resulting product until the resulting product (e.g., polymer-coated silicon material) is neutral. For instance, the ratio (e.g., molar ratio) of the polymer precursors can be 0.5:1:1 phytic acid:pyrorole:APS. The resulting product can be dried in a vacuum oven at a temperature between 40° C. and 80° C. for between 1 to 24 hours.

In a second illustrative example, a silicon material can be coated by: mixing (e.g., stirring, sonicating, etc.) a polymer (e.g., PAN) and the silicon material in a solvent (e.g., N,N-dimethylformamide (DMF)); evaporating the solvent from the mixture (e.g., heating to a temperature between 60-100° C., using a vacuum, sparging, etc.); heating the resulting composite (the dried polymer/silicon mixture) to a temperature between 200-400° C. (e.g., at a ramp rate of about 5° C./min) and maintaining the composite at the temperature for between 1 and 24 hours; and comminuting (e.g., ball milling) the final product. The ratio (e.g., weight ratio) of the polymer to silicon material can be 3:7.

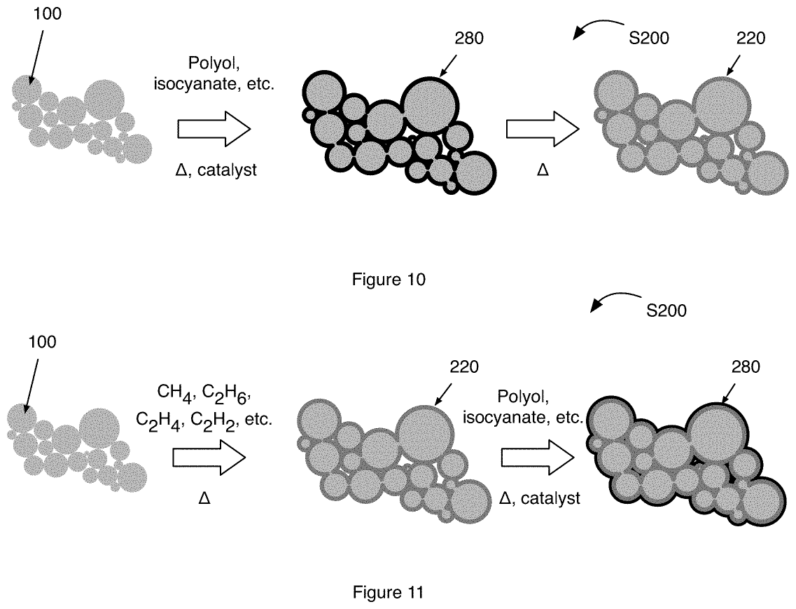

In a third specific example as shown for instance in FIG. 10, a polymer coated silicon material can be heated (e.g., in an inert atmosphere, in a reducing atmosphere, etc.) to a temperature between about 600-1100° C. to carbonize (e.g., reduce, convert the polymer to carbon) the polymer.

In a fourth specific example as shown for instance in FIG. 8, a silicon material can be heated to between about 500° C. and 1200° C. under argon with a flow rate between 100 standard cubic centimeters per minute (SCCM)-5000 SLM (standard liters per minute) and, optionally, hydrogen (H₂) with a flow rate between 10 SCCM-5000 SLM. The pressure can be maintained between about 10-720 torr. Ethyne (C₂H₂), ethene (C₂H₄), ethane (C₂H₆), and/or methane (CH₄) (e.g., standard grade, semiconductor grade, etc.) can be introduced at a flow rate between 100 SCCM-5000 SLM can be introduced for between 20 minutes and 90 minutes.

In a fifth specific example, a silicon material can be heated to between about 500° C. and 1200° C. under argon with a flow rate between 10 SCCM-5000 SLM and hydrogen (H₂) with a flow rate between 10 SCCM-5000 SLM. The pressure can be maintained between about 500-750 torr. Ethyne (C₂H₂), ethene (C₂H₄), ethane (C₂H₆), and/or methane (CH₄) can be introduced at a flow rate between 10 SCCM-5000 SLM can be introduced for between 15 minutes and 30 minutes to carbon coat (or carbon load) the silicon.

In a sixth specific example, a silicon material can be coated by

In a seventh specific example as shown for instance in FIG. 7 or FIG. 11, two or more coating methods (e.g., two or more of the preceding examples) can be performed (e.g., in sequence, simultaneously, concurrently, contemporaneously, etc.) to generate a silicon material with two or more coatings (and/or a single coating that is generated in two or more ways, which can be beneficial for achieving a target loading, coating uniformity, coating property, etc.).

Modifying the coating S300 preferably functions to modify a coating to improve a coating property (e.g., mechanical stability, resilience, thermal stability, brittleness, electrical conductivity, ionic conductivity, etc.). The coating can be modified before, during, and/or after the silicon material is coated. The coating can be modified in the same chamber (e.g., environment) and/or a different chamber from the chamber used to coat the silicon material.

The coating can be modified (e.g., activated, cyclized, enhanced, etc.) thermally, using pressure, optically, using one or more chemical reagents, and/or in any manner.

In a specific example, a coating (e.g., a coating disposed on the silicon material) can be converted to a different form. For instance, a polyacrylonitrile (PAN) coating can be converted to a cyclized form by thermal decomposition. The thermal decomposition is preferably, but not exclusively, performed in an inert atmosphere. The thermal decomposition can be performed at a temperature between 50-500° C. (e.g., 50° C., 100° C., 150° C., 200° C., 250° C., 300° C., 400° C., 450° C., 500° C., values and/or ranges therebetween, etc.), at a temperature below 50° C., and/or at a temperature above 500° C. The thermal decomposition can be performed for (e.g., temperature can be maintained for) between 1-24 hr (e.g., 1 hour, 2 hours, 4 hours, 6 hours, 8 hours, 12 hours, 15 hours, 18 hours, 24 hours, values or ranges therebetween, etc.), less than 1 hour, and/or greater than 24 hours.

However, the coating can otherwise be modified.

Embodiments of the system and/or method can include every combination and permutation of the various system components and the various method processes, wherein one or more instances of the method and/or processes described herein can be performed asynchronously (e.g., sequentially), concurrently (e.g., in parallel), or in any other suitable order by and/or using one or more instances of the systems, elements, and/or entities described herein.

As a person skilled in the art will recognize from the previous detailed description and from the figures and claims, modifications and changes can be made to the preferred embodiments of the invention without departing from the scope of this invention defined in the following claims.

We claim:

1. A method comprising:
mixing silica fumes with a reducing agent;
reducing the silica fumes to silicon by heating the mixture of the silica fumes and the reducing agent to a reducing temperature in an inert environment; and
coating the silicon with graphitic carbon using chemical vapor deposition.

2. The method of claim 1, wherein a carbon source for the chemical vapor deposition comprises at least one of methane, ethane, ethene, or ethyne; wherein a flow rate of the carbon source is between about 30-600 standard cubic centimeters per minute.

3. The method of claim 2, wherein the graphitic carbon is deposited at a temperature between about 700° C. and about 1000° C.

4. The method of claim 3, wherein the carbon source is flowed for between about 5 and about 90 minutes.

5. The method of claim 1, wherein the reducing temperature is between about 600-900° C., wherein the mixture is maintained at the reducing temperature for between about 1 and about 12 hours.

6. The method of claim 5, further comprising heating the mixture to an intermediate temperature between about 500° C. and about 700° C. before heating the mixture to the reducing temperature.

7. The method of claim 6, wherein the mixture is maintained at the intermediate temperature for between about 1 hour and about 12 hours.

8. A method comprising:
mixing a silicon material with a polymer, wherein the silicon material comprises primary particles that are clustered into secondary particles; and
heating the mixture of the silicon material and the polymer to a treatment temperature for a treatment time.

9. The method of claim 8, wherein heating the mixture cyclizes the polymer.

10. The method of claim 8, wherein the treatment temperature is between about 200° C. and about 400° C., wherein the treatment time is between about 1 hour and about 12 hours.

11. The method of claim 8, wherein the polymer comprises at least one of polyisoprene, polybutadiene, chloroprene rubber, butyl rubber, styrene-butadiene rubber, nitrile rubber, ethylene propylene rubber, ethylene propylene diene rubber, epichlorohydrin rubber, polyacrylic rubber, silicone rubber, fluorosilicone rubber, polyacrylonitrile, or polypyrrole.

12. The method of claim 8, wherein mixing the silicon material with the polymer comprises mixing the silicon material with polymeric precursors.

13. The method of claim 12, wherein the polymer comprises polyacrylonitrile, and wherein the polymeric precursors are configured to form a second polymer.

14. The method of claim 13, wherein the polymeric precursors comprise a polyol and a diisocyanate.

15. The method of claim 14, further comprising coating the polymer coated silicon material with a second coating.

16. The method of claim 8, wherein a composition of the silicon material is between about 2 and about 10% carbon, between about 1% and about 5% oxygen, and between about 85% and about 97% silicon.

17. A method comprising:
a) exposing silicon particles to a coating reagent;
b) heating the silicon particles and the coating reagent to a coating temperature; and
c) agitating the silicon particles contemporaneously with (a) or (b).

18. The method of claim 17, wherein agitating the silicon particles comprises rotating a container holding the silicon particles, wherein the container comprises one or more blades on a surface of the container, wherein the silicon particles contact the blades during operation.

19. The method of claim 17, wherein the silicon particles comprise silicon nanoparticles with a size between about 2 and 100 nm that are fused together.

20. The method of claim 17, wherein the silicon particles are made from silica fumes.
